(19) United States
(12) Patent Application Publication
(10) Pub. No.: US 2025/0237926 A1
(43) Pub. Date: Jul. 24, 2025

(54) VIEWING ANGLE CONTROL FILM AND DISPLAY DEVICE HAVING THE SAME

(71) Applicant: LG Display Co., Ltd., Seoul (KR)

(72) Inventors: SangHyun LEE, Seongnam-si (KR); MinSoo PARK, Anyang-si (KR)

(73) Assignee: LG Display Co., Ltd., Seoul (KR)

(21) Appl. No.: 18/774,356

(22) Filed: Jul. 16, 2024

(30) Foreign Application Priority Data
Jan. 23, 2024 (KR) 10-2024-0010083

(51) Int. Cl. G02F 1/29

(52) U.S. Cl. CPC G02F 1/29

(57) ABSTRACT

A viewing angle control film may include a lower electrode, a plurality of viewing angle patterns disposed over the lower electrode, an ink layer disposed in a space between the plurality of viewing angle patterns, an upper electrode disposed over the viewing angle pattern and the ink layer, and a plurality of barriers disposed over the upper electrode, in which the ink layer may include a first particle and a second particle having different particle charge amounts. A display device including a viewing angle control film is also disclosed.

### CROSS-REFERENCE TO RELATED APPLICATIONS

This application claims the benefit of and priority to Korean Patent Application No. 10-2024-0010083 filed on Jan. 23, 2024, in the Korean Intellectual Property Office, the entire disclosure of which is incorporated herein by reference for all purposes.

### BACKGROUND

### Technical Field

The present disclosure relates to a viewing angle control film and a display device including the same, and more specifically, to a viewing angle control film capable of controlling a viewing angle and a display device including the same.

### Description of the Related Art

Recently, as the importance of user privacy protection increases, a display device including a viewing angle control film for privacy protection has been provided. The display device limits the viewing angle of the display device through the viewing angle control film, thereby preventing people around users except the users from viewing images within the display device.

The description of the related art should not be assumed to be prior art merely because it is mentioned in or associated with this section. The description of the related art includes information that describes one or more aspects of the subject technology, and the description in this section does not limit the invention.

### SUMMARY

A fixed-type viewing angle control film may be applied to control the viewing angle. The existing fixed barrier film blocks light incident on a side surface by stacking black stripe barrier patterns in a multi-layer.

However, in the case of the existing fixed barrier film, when an aperture ratio increases to improve a frontal transmittance, a lateral shielding rate decreases, so it is difficult to implement a privacy mode. In addition, as the number of layers increases to improve the aperture ratio, an alignment tolerance increases, and because the viewing angle control film is a fixed type, in one or more aspects, it may be impossible to switch between a privacy mode and a share mode according to user needs.

One or more aspects of the present disclosure are directed to providing a viewing angle control film capable of securing both a frontal transmittance and a lateral shielding rate and a display device including the same.

One or more other aspects of the present disclosure are directed to providing a viewing angle control film capable of freely switching between a privacy mode and a share mode according to user needs, and a display device including the same.

Aspects of the present disclosure are not limited to the above-mentioned aspects, and other aspects, which are not mentioned above, can be clearly understood by those skilled in the art from the following descriptions.

According to an aspect of the present disclosure, a viewing angle control film includes a lower electrode, a plurality of viewing angle patterns disposed over the lower electrode, an ink layer disposed in a space between the plurality of viewing angle patterns, an upper electrode disposed over the viewing angle pattern and the ink layer, and a plurality of barriers disposed over the upper electrode, in which the ink layer may include a first particle and a second particle having different particle charge amounts.

According to another aspect of the present disclosure, a display device includes a display panel, and a viewing angle control film positioned over or below the display panel, in which the viewing angle control film may include a lower electrode, a plurality of viewing angle patterns disposed over the lower electrode, an ink layer disposed in a space between the plurality of viewing angle patterns, an upper electrode disposed over the viewing angle pattern and the ink layer, and a plurality of barriers disposed over the upper electrode. The ink layer may include a first particle and a second particle having different particle charge amounts.

Other detailed matters of the exemplary embodiments are included in the detailed description and the drawings.

According to one or more aspects of the present disclosure, it is possible to secure both a frontal transmittance and a lateral shielding rate by applying bi-stability electrophoretic ink of black and white dual particles to a multi-layered structure of the black stripe barrier and the dual active barrier.

According to one or more aspects of the present disclosure, it is possible to freely switch between the privacy mode and the share mode according to user needs, reduce power consumption by applying the bi-stability electrophoretic ink, and prevent defects due to particle agglomeration during the long-term operation. In addition, by reducing the power consumption to reduce the generation of greenhouse gases due to the use of power, it is possible to implement environment/social/governance (ESG).

According to one or more aspects of the present disclosure, by applying the dual particles of black and white to increase the amount of light to be recycled, it is possible to improve luminance.

The effects according to one or more aspects of the present disclosure are not limited to the contents exemplified above, and more various effects are included in the present specification.

Other aspects, effects, devices, methods, features and advantages will be, or will become, apparent to one with skill in the art upon examination of the drawings and detailed description herein. It is intended that all such aspects, effects, devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a block diagram for describing a liquid crystal display device according to a first exemplary embodiment of the present disclosure;

FIG. 2 is a cross-sectional view schematically illustrating the liquid crystal display device of FIG. 1;

FIG. 3 is a cross-sectional view exemplarily illustrating a viewing angle control film according to a first exemplary embodiment of the present disclosure;

FIG. 4 is a perspective view exemplarily illustrating the viewing angle control film according to the first exemplary embodiment of the present disclosure;

FIG. 5A is a cross-sectional view for describing a method of implementing a privacy mode in the viewing angle control film of FIG. 3;

FIG. 5B is a cross-sectional view for describing a method of implementing a share mode in the viewing angle control film of FIG. 3;

FIGS. 6A to 6E are perspective views for describing a method of driving a viewing angle control film of FIG. 4 as an example;

FIG. 7 is a cross-sectional view exemplarily illustrating a viewing angle control film according to a second exemplary embodiment of the present disclosure;

FIG. 8 is a cross-sectional view schematically illustrating a liquid crystal display device of a third exemplary embodiment of the present disclosure; and

FIG. 9 is a cross-sectional view schematically illustrating an organic electroluminescent display device according to a fourth exemplary embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

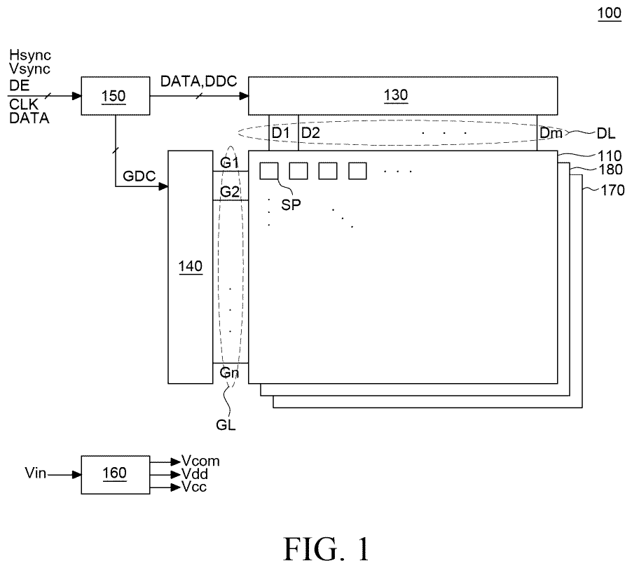

FIG. 1 is a block diagram for describing a liquid crystal display device according to a first exemplary embodiment of the present disclosure.

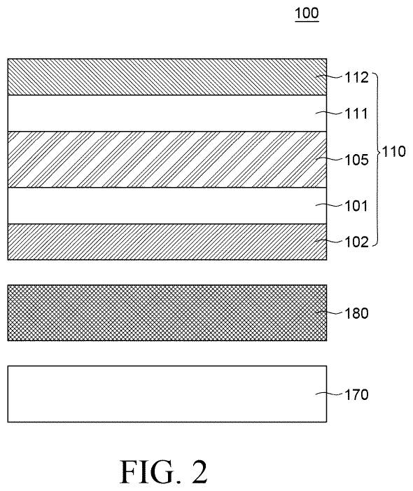

FIG. 2 is a cross-sectional view schematically illustrating the liquid crystal display device of FIG. 1.

Hereinafter, a liquid crystal display device is used as, for example, a display device, but the present disclosure is not limited thereto.

Referring to FIGS. 1 and 2, a liquid crystal display device 100 according to a first exemplary embodiment of the present disclosure may be divided into a display area and a non-display area and may be configured by a display panel 110 in which pixels SP are arranged in a matrix form in the display area, a backlight unit 170 that is disposed below the display panel 110 and provides a light source, and drivers 130, 140, and 150 and a power supply unit 160 that are mounted in the non-display area of the display panel 110 to drive the pixels SP.

For example, when the display device is the liquid crystal display device, the display panel 110 may be a liquid crystal panel.

The drivers 130, 140, and 150 may include, but are not limited to, a gate driver 140, a data driver 130, and a timing driver 150.

The timing driver 150 may receive a vertical synchronization signal Vsync, a horizontal synchronization signal Hsync, a data enable signal DE, a clock signal CLK, and a data signal DATA.

A control signal generated by the timing driver 150 may include a gate timing control signal GDC to control an operation timing of the gate driver 140 and a data timing control signal DDC to control an operation timing of the data driver 130.

The display panel 110 may include a thin film transistor substrate (hereinafter referred to as a lower substrate) 101, a color filter substrate (hereinafter referred to as an upper substrate) 111, and a liquid crystal layer 105 injected between these substrates 101 and 111, and the plurality of pixels SP may be arranged in the matrix form.

In addition, the display panel 110 may include a seal pattern formed of a sealant for bonding between the upper substrate 111 and the lower substrate 101. For example, a seal pattern may be formed in the non-display area at edges of the upper substrate 111 and the lower substrate 101.

One pixel SP may be defined by a data line DL (including D1, D2, . . . , Dm) and a gate line GL (including G1, G2, . . . , Gn) that intersect each other.

One pixel SP includes a TFT that is driven by a gate signal supplied through the gate line GL, a storage capacitor that stores a data signal supplied through the data line DL as a data voltage, and a liquid crystal cell that is driven by the data voltage stored in the storage capacitor. The liquid crystal cell may be driven by a data voltage supplied to a pixel electrode and a common voltage supplied to a common electrode.

Polarizers 102 and 112 may each be attached to outsides of the lower substrate 101 and the upper substrate 111 of the display panel 110 configured as described above, and an alignment film for setting a pre-tilt angle of a liquid crystal may be formed on an inside thereof, respectively.

The lower polarizer 102 polarizes light transmitting the backlight unit 170, and the upper polarizer 112 polarizes light transmitting the liquid crystal layer 105.

In addition, a data link line and a gate link line each connected to the data line DL and the gate line GL may be formed in the non-display area. In addition, a data pad and a gate pad may be connected to ends of the data link line and the gate link line, respectively.

The data pad and the gate pad may be connected to a data driving IC and a gate driving IC mounted on the lower substrate 101, respectively.

The data driving IC and the gate driving IC may be connected to an external printed circuit board through Flexible Printed Circuit (FPC). The printed circuit board may include the timing driver 150 and the power supply unit 160. However, the present disclosure is not limited thereto.

The backlight unit 170 may provide light to the display panel 110. For example, the backlight unit 170 may include a light source that emits light, a light guide plate that guides light to the display panel 110, an optical sheet that concentrates and diffuses light, etc.

The power supply unit 160 may convert input power Vin supplied from the outside into direct current power and output a common voltage Vcom, a first high voltage Vdd, a second high voltage Vcc, etc.

The common voltage Vcom may be supplied to a common voltage line, while the first high voltage Vdd may be supplied to the gate driver 140 and the data driver 130, and the second high voltage Vcc may be supplied to the timing driver 150. The power supply unit 160 may be mounted on the printed circuit board connected to the display panel 110. However, the present disclosure is not limited thereto.

Meanwhile, according to one or more aspects of the present disclosure, a viewing angle control film 180 for controlling the viewing angle is provided between the display panel 110 and the backlight unit 170. However, the present disclosure is not limited thereto, and the viewing angle control film 180 of the present disclosure may be provided over the display panel 110.

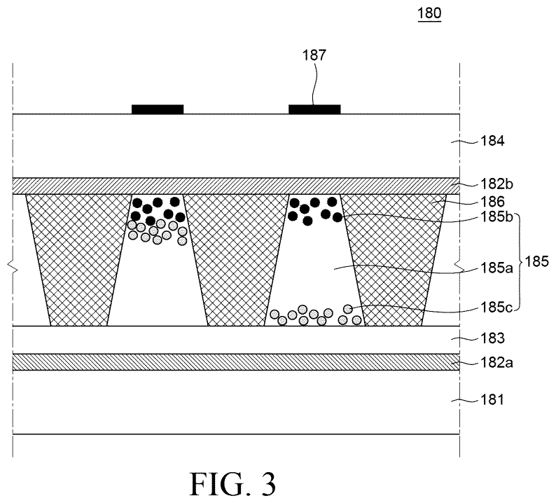

In addition, the viewing angle control film 180 according to the first exemplary embodiment of the present disclosure is configured to include an active barrier and a black stripe barrier that control the viewing angle by forming electrodes over and below a viewing angle pattern, for example, a louver pattern, which will be described in detail with reference to FIG. 3 below.

FIG. 3 is a cross-sectional view exemplarily illustrating the viewing angle control film according to the first exemplary embodiment of the present disclosure.

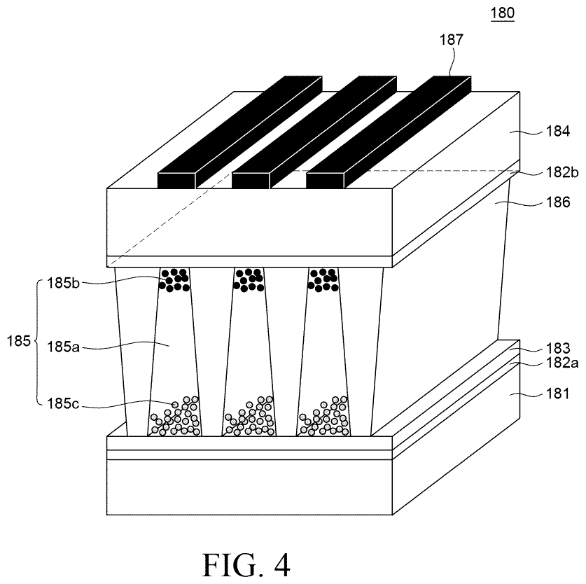

FIG. 4 is a perspective view exemplarily illustrating the viewing angle control film according to the first exemplary embodiment of the present disclosure.

FIGS. 3 and 4 are a cross-sectional view and a perspective view illustrating a portion of the viewing angle control film 180 according to the first exemplary embodiment of the present disclosure as an example.

Referring to FIGS. 3 and 4, the viewing angle control film 180 according to the first exemplary embodiment of the present disclosure may largely include an upper electrode 182b, a lower electrode 182a, and a louver pattern, for example, a viewing angle pattern 186 disposed between the upper electrode 182b and the lower electrode 182a.

The lower electrode 182a may be disposed over the lower substrate 181.

The upper electrode 182b may be disposed below the upper substrate 184.

For example, the lower substrate 181 may be composed of a base film (or base substrate), and the upper substrate 184 may be composed of a protective film (or another base film).

For example, polycarbonate (PC) or polyethylene terephthalate (PET) may be used as the base film and the protective film.

An adhesive layer 183 may be disposed over the lower electrode 182a.

The adhesive layer 183 may be formed of an optically clear adhesive (OCA) or an optically clear resin (OCR).

The viewing angle pattern 186 may be disposed on the adhesive layer 183.

The viewing angle pattern 186 may be disposed on the adhesive layer 183 at predetermined intervals (pitch).

For example, the viewing angle pattern 186 may be formed of a transparent material so that light may transmit, but the present disclosure is not limited thereto. For example, the viewing angle pattern 186 may be formed of a transparent resin. The resin may be an acrylic type, but is not limited thereto.

For example, the viewing angle pattern 186 may have a trapezoidal cross section, but is not limited thereto. For example, the viewing angle pattern 186 may have a trapezoidal shape in which a top surface in contact with the upper electrode 182b is wider than a bottom surface in contact with the lower electrode 182a. The viewing angle pattern 186 may have a rectangular or square cross section or may also have a triangular cross section.

For example, the viewing angle patterns 186 may be arranged side by side in one direction, but are not limited thereto. A certain space may be formed between the plurality of viewing angle patterns 186 arranged side by side in one direction. For example, the respective space (or intervals) formed between the plurality of viewing angle patterns 186 may have a trapezoidal shape in which the top surface is wider than the bottom surface, but is not limited thereto. For example, the space formed between the plurality of viewing angle patterns 186 may be arranged side by side in one direction along the plurality of viewing angle pattern 186, but is not limited thereto.

The viewing angle control film 180 according to the first exemplary embodiment of the present disclosure may further include an ink layer 185 provided in the space between the plurality of viewing angle patterns 186.

The upper electrode 182b may be disposed over the viewing angle pattern 186 and the ink layer 185.

The upper electrode 182b and the lower electrode 182a may be formed of a transparent conductive material such as tin oxide (TO), indium tin oxide (ITO), indium zinc oxide (IZO), and indium tin zinc oxide (ITZO), but is not limited thereto.

In addition, the upper substrate 184 may be disposed over the upper electrode 182b.

In addition, a stripe-type barrier 187 may be disposed on the top surface of the upper substrate 184.

For example, the barrier 187 may be formed of a black-based material.

For example, the barrier 187 may be positioned corresponding to the space between the plurality of viewing angle patterns 186 in which the ink layer 185 is disposed.

For example, the plurality of barriers 187 may be disposed side by side in one direction along the respective spaces between the plurality of viewing angle patterns 186.

The viewing angle control film 180 of the first exemplary embodiment of the present disclosure may transmit parallel light incident between the barriers 187 by the barrier 187 disposed on the top surface of the upper substrate 184 and block light incident in an inclination direction toward the barrier 187, thereby controlling the viewing angle. In other words, the barrier 187 may function to block light incident from the side surface.

In particular, the present disclosure allows a gap between the barriers 187 to be further increased as the barrier 187 is disposed on the top surface of the upper substrate 184 which is relatively far away from the lower substrate 181 on which light is incident, thereby improving a frontal transmittance without lowering a lateral shielding rate. When the barriers 187 are disposed on the same layer as the lower substrate 181 and an aperture ratio increases by increasing the gap between the barriers 187 to improve the frontal transmittance, the lateral shielding rate may decrease, making it difficult to implement the privacy mode. On the other hand, as the barrier 187 is disposed at a relatively high layer, the lateral shielding rate may be improved for the gap between the same barriers 187.

Meanwhile, the present disclosure applies the bi-stability electrophoretic ink of black and white dual particles 185b and 185c to a multi-layered structure of a black stripe barrier 187 and a dual active barrier, thereby simultaneously securing the frontal transmittance and the lateral shielding rate. Here, the lower electrode 182a, the viewing angle pattern 186, the ink layer 185, and the upper electrode 182b sequentially stacked between the lower substrate 181 and the upper substrate 184 may constitute an active barrier.

To this end, the ink layer 185 may include the first particle 185b and the second particle 185c provided in the solvent 185a.

For example, the solvent 185a may be a transparent organic solvent.

In addition, for example, the first particle 185b may be formed of black ink such as carbon, and the second particle 185c may be formed of white ink, but are not limited thereto.

In addition, the first particle 185b and the second particle 185c may have different particle charge amounts. There is a difference in reaction rate depending on the particle charge amount, and this difference in reaction rate may be used to implement separation of layers between particles and mode switching. For example, the second particle 185c may have a larger particle charge amount than the first particle 185b.

The first particle 185b and the second particle 185c may be the bi-stability electrophoretic ink.

The bi-stability electrophoretic ink may maintain a current mode without a maintenance voltage to reduce power consumption, and improve ink agglomeration due to the long-term operation to improve driving reliability.

For reference, in a dispersed electrophoretic ink, particles coated with negative charges move toward a positive (+) pole by an electric field, and when a voltage is cut off, the particles are dispersed due to inter-particle repulsion.

On the other hand, in the bi-stability electrophoretic ink, the particles coated with negative charges move toward a positive (+) pole by an electric field and maintain their current state even when a voltage is cut off.

When using the bi-stability electrophoretic ink as in the present disclosure, there is no need to apply an electric field when maintaining the share mode or privacy mode, thereby reducing the power consumption and preventing the occurrence of defects due to the particle agglomeration during the long-term operation.

Hereinafter, a method of implementing a privacy mode and a share mode depending on whether a voltage is applied will be described in detail with reference to the drawings.

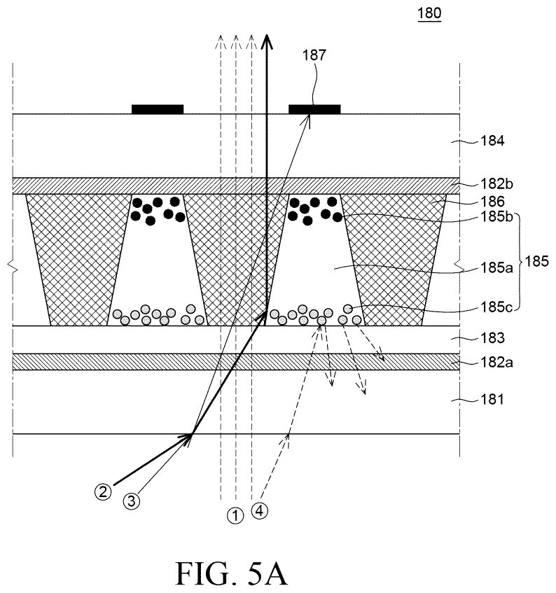

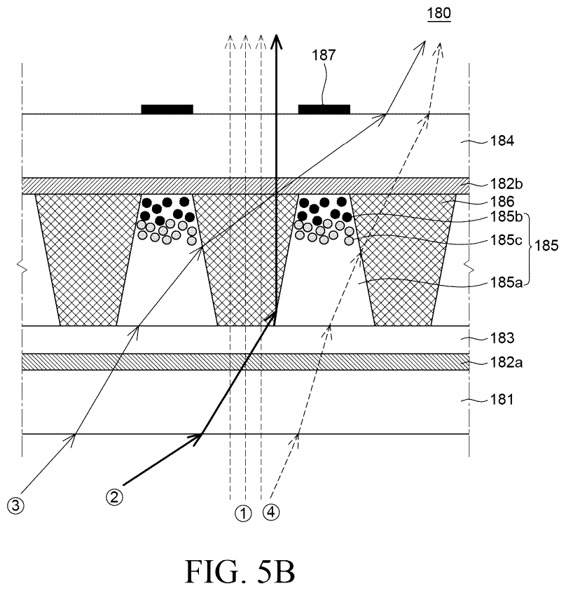

FIG. 5A is a cross-sectional view for describing a method of implementing a privacy mode in the viewing angle control film of FIG. 3.

FIG. 5B is a cross-sectional view for describing a method of implementing a share mode in the viewing angle control film of FIG. 3.

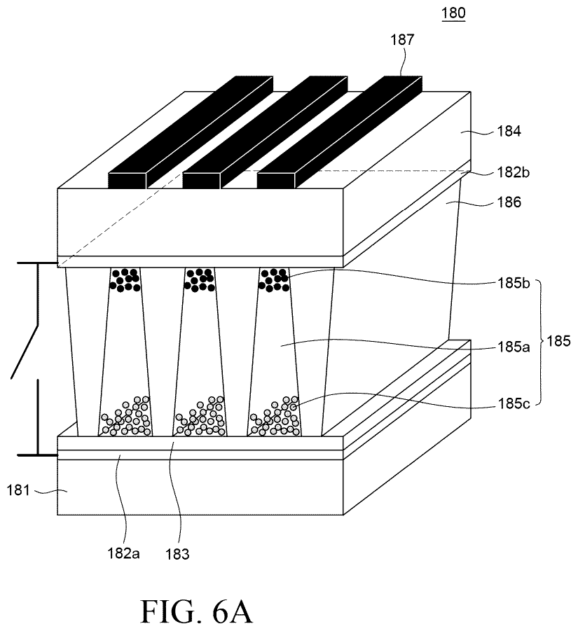

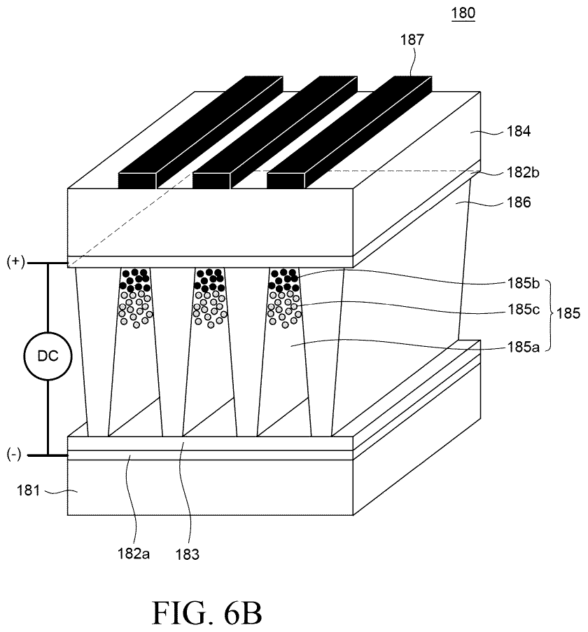

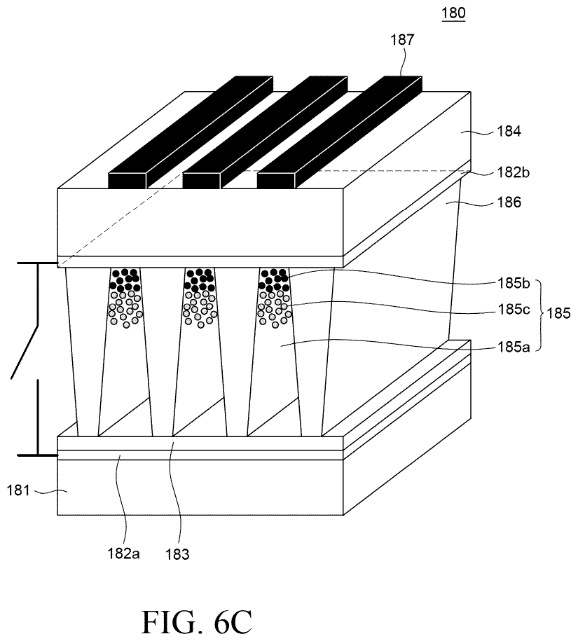

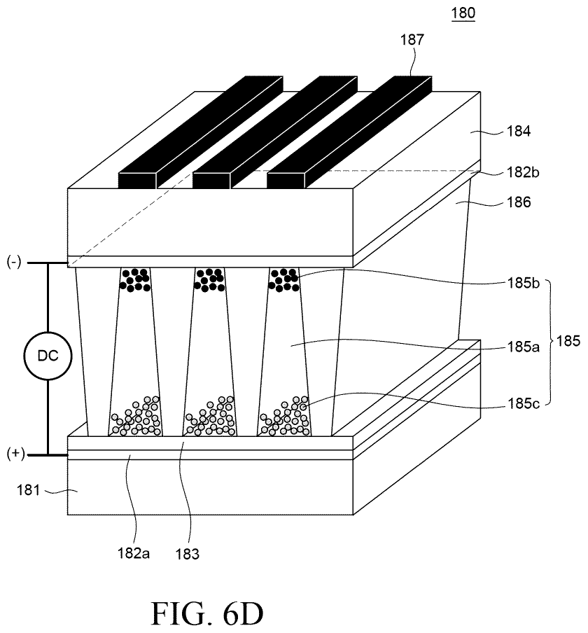

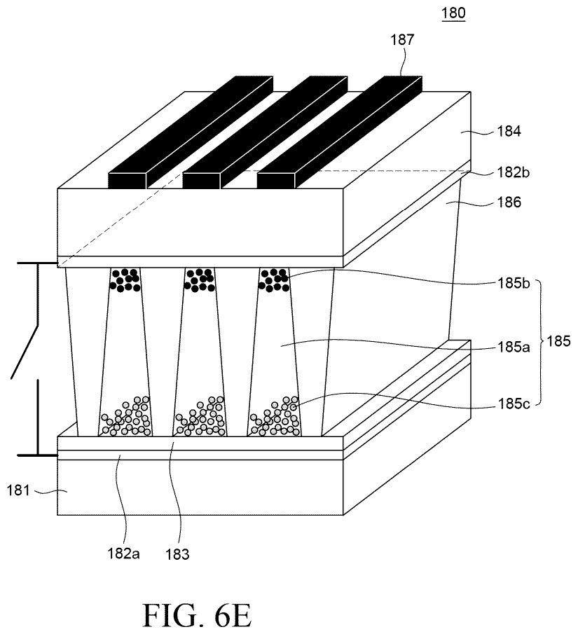

FIGS. 6A to 6E are perspective views for describing a method of driving a viewing angle control film of FIG. 4 as an example.

Referring to FIGS. 5A and 6A, when no voltage is applied, the first particles 185b and the second particles 185c may maintain their positions in the space between the plurality of viewing angle patterns 186.

The first particle 185b and the second particle 185c are composed of the bi-stability electrophoretic ink. For example, the first particle 185b may be composed of the black ink, and the second particle 185c may be composed of the white ink.

In addition, the first particle 185b and the second particle 185c may have different particle charge amounts. For example, the second particle 185c may have a larger particle charge amount than the first particle 185b.

Layer separation between particles may be achieved through the difference in reaction rate between particles. For example, the first particle 185b may be positioned near the upper electrode 182b, and the second particle 185c may be positioned near the lower electrode 182a. In this case, light \textcircled{1} incident in parallel toward the plurality of viewing angle patterns 186 may transmit and travel between the upper barriers 187 through the viewing angle patterns 186. In addition, among light \textcircled{2} and \textcircled{3} incident obliquely toward the plurality of viewing angle patterns 186, some of the light \textcircled{2} hitting an inclined surface of the viewing angle pattern 186 may be reflected by total reflection and transmit and travel between the upper barriers 187. For example, the total reflection may occur on the inclined surface of the viewing angle pattern 186 due to a difference in refractive index between the viewing angle pattern 186 and the ink layer 185, thereby improving the frontal transmittance. In addition, among the light \textcircled{2} and \textcircled{3} incident obliquely toward the plurality of viewing angle patterns 186, some other light \textcircled{3} transmitting the viewing angle pattern 186 may be blocked by the barrier 187. In addition, light \textcircled{4} incident on the ink layer 185 between the plurality of viewing angle patterns 186 may be reflected and blocked by the second particles 185c of the white ink positioned at the lower side. In this way, the lateral shielding rate may be secured using the total reflection on the inclined surface of the viewing angle pattern 186 and the second particles 185c of the ink layer 185.

In this case, the privacy mode may be implemented by allowing light to travel only to the front viewing angle. In addition, it is possible to secure both the frontal transmittance and lateral shielding rate. For example, Table 1 below may be referenced.

TABLE 1

| | Comparative | Privacy | Share |
|---|---|---|---|
| | Embodiment | Mode | Mode |
| Frontal luminance | 882.7 | 642.4 | 635.2 |
| Frontal Transmittance | 100% | 73% | 72% |
| Lateral Luminance (29 degrees or 29°) | 602.61 | 14.35 | 448.33 |
| Lateral Transmittance (29°) | 68.3% | 2.2% | 70.6% |
| Lateral Luminance (−29°) | 608.00 | 105.63 | 489.81 |
| Lateral Transmittance (−29°) | 68.9% | 16.4% | 77.1% |

Referring to Table 1, for example, for the privacy mode, it could be seen that the frontal transmittance is about 73% relative to the comparative embodiment without the viewing angle pattern 186, and the lateral transmittance at 29° and −29° is about 2.2 to 16.4%. In addition, for the share mode, it could be seen that the frontal transmittance is about 72% relative to the comparative embodiment without the viewing angle pattern 186, and the lateral transmittance at 29° and −29° is about 70.6 to 77.1%.

In addition, the greater the width, pitch, and inclination angle of the ink layer 185, which is a shielding part, the greater the effect of increasing front luminance. For example, it could be seen that, at the same inclination angle, when the width and pitch of the ink layer 185 are 12 and 42 μm, respectively, the luminance increase efficiency is 110.7%, whereas when the width and pitch of the ink layer 185 are 29 and 60 μm, respectively, the luminance increase efficiency is 132.0%.

For reference, the total reflection may occur on the inclined surface of the viewing angle pattern 186 due to the difference in refractive index between the viewing angle pattern 186 and the ink layer 185 and the inclination angle of the viewing angle pattern 186, so the frontal transmittance may be improved. The greater the difference in refractive index, the more likely it is that the total reflection occurs. For example, referring to Table 2 below, in S-polarized light, when the difference Δn in refractive index is 0.035, the surface reflectance increases as the incident angle increases, but the total reflection does not occur. For example, it can be seen that the surface reflectance is 0.59, 1.65, and 2.85% at incident angles of 65°, 70°, and 72°, respectively. In addition, it can be seen that, when the difference in refractive index is 0.07, the surface reflectance further increases as the incident angle increases, but the total reflection does not occur. For example, it can be seen that the surface reflectance is 3.12, 13.01, and 42.08% at incident angles of 65°, 70°, and 72°, respectively. On the other hand, it can be seen that, when the difference in refractive index is 0.1, the surface reflectance further increases as the incident angle increases, and the total reflection occurs at the incident angle of 70° or more. For example, it can be seen that the surface reflectance is 8.90 and 60.70% at the incident angles of 65° and 69°, and the total reflection occurs at the incident angles of 70° or more.

TABLE 2

| Incident Angle (Θi) | Δn 0.10 | Δn 0.07 | Δn 0.035 |
|---|---|---|---|
| 72 | Total Reflection | 42.08% | 2.85% |
| 71 | Total Reflection | 20.74% | 2.14% |
| 70 | Total Reflection | 13.01% | 1.65% |
| 69 | 60.70% | 8.99% | 1.30% |
| 68 | 27.19% | 6.57% | 1.04% |
| 67 | 17.14% | 4.99% | 0.85% |
| 66 | 12.00% | 3.90% | 0.70% |
| 65 | 8.90% | 3.12% | 0.59% |

In addition, for example, referring to Table 3 below, it can be seen that in P-polarized light, when the difference in refractive index is 0.035, the surface reflectance increases as the incident angle increases, but the total reflection does not occur. For example, it can be seen that the surface reflectance is 0.28, 1.09, and 2.11% at the incident angles of 65°, 70°, and 72°, respectively. In addition, it can be seen that, when the difference in refractive index is 0.07, the surface reflectance further increases as the incident angle increases, but the total reflection does not occur. For example, it can be seen that the surface reflectance is 1.69, 10.14, and 38.46% at the incident angles of 65°, 70°, and 72°, respectively. On the other hand, it can be seen that, when the difference in refractive index is 0.1, the surface reflectance further increases as the incident angle increases, and the total reflection occurs at the incident angle of 70° or more. For example, it can be seen that the surface reflectance is 5.55 and 56.41% at the incident angles of 65° and 69°, and the total reflection occurs at the incident angles of 70° or more.

TABLE 3

| Incident Angle (Θi) | Δn 0.10 | Δn 0.07 | Δn 0.035 |
|---|---|---|---|
| 72 | Total Reflection | 38.46% | 2.11% |
| 71 | Total Reflection | 17.37% | 1.50% |
| 70 | Total Reflection | 10.14% | 1.09% |
| 69 | 56.41% | 6.54% | 0.81% |
| 68 | 22.14% | 4.46% | 0.61% |
| 67 | 12.71% | 3.15% | 0.47% |
| 66 | 8.16% | 2.29% | 0.36% |
| 65 | 5.55% | 1.69% | 0.28% |

Next, referring to FIGS. 5B and 6B, when the DC voltage is applied between the upper electrode 182b and the lower electrode 182a in the above-described privacy mode, the privacy mode may be switched to the share mode.

For example, when a positive (+) voltage is applied to the upper electrode 182b and a negative (−) voltage is applied to the lower electrode 182a, the first particle 185b and the second particle 185c with a negative (−) charge move toward the upper electrode 182b which is a positive (+) pole. In this case, the first particle 185b, which is close to the upper electrode 182b, may first reach the upper electrode 182b, and then the second particle 185c may move toward the upper electrode 182b.

In this case, light \textcircled{1} incident in parallel toward the plurality of viewing angle patterns 186 may transmit and travel between the upper barriers 187 through the viewing angle patterns 186. In addition, among light \textcircled{2}, \textcircled{3}, and \textcircled{4} incident obliquely toward the plurality of viewing angle patterns 186, some of the light \textcircled{2} incident obliquely to a boundary between the viewing angle pattern 186 and the ink layer 185 through the viewing angle pattern 186 may be reflected by the total reflection and transmit and travel between the barriers 187. As described above, the total reflection may occur on the inclined surface of the viewing angle pattern 186 due to the difference in refractive index between the viewing angle pattern 186 and the ink layer 185, thereby improving the frontal transmittance. In addition, among light \textcircled{2}, \textcircled{3}, and \textcircled{4} incident obliquely toward the plurality of viewing angle patterns 186, some of the light \textcircled{3} and \textcircled{4} incident obliquely to the boundary between the ink layer 185 and the viewing angle pattern 186 through the ink layer 185 may be refracted and thus transmit and travel between the barriers 187 through the viewing angle pattern 186. For example, as the DC voltage is applied between the upper electrode 182b and the lower electrode 182a and the second particle 185c moves toward the upper electrode 182b, some of the light \textcircled{3}, \textcircled{4} is obliquely incident to the boundary between the ink layer 185 and the viewing angle pattern 186 through the ink layer 185, and may then be refracted (without totally reflected) on the inclined surface of the ink layer 185 and thus transmit and travel between the barriers 187 through the viewing angle pattern 186. Therefore, the privacy mode may be switched to the share mode by allowing the light to transmit not only at the front viewing angle but also at the inclination viewing angle.

For example, for the share mode, it could be seen that the frontal transmittance is about 72% relative to the comparative embodiment without the viewing angle pattern 186, and the lateral transmittance at 29° and −29° is about 70.6 to 77.1%.

Next, referring to FIGS. 5B and 6C, even if the voltage applied between the upper electrode 182b and the lower electrode 182a is cut off, the first particle 185b and the second particle 185c due to the nature of the bi-stability ink may maintain their current state (e.g., position and distribution). Therefore, the share mode state may be maintained without applying the voltage, the power consumption may be reduced in the share mode, and the defects due to the particle agglomeration during the long-term operation may be prevented.

Next, referring to FIGS. 5A and 6D, when the DC voltage is applied between the upper electrode 182b and the lower electrode 182a in the share mode, the share mode may be switched to the privacy mode.

For example, when a negative (−) voltage is applied to the upper electrode 182b and a positive (+) voltage is applied to the lower electrode 182a, the first particle 185b and the second particle 185c with the negative (−) charge move toward the lower electrode 182a which is the positive (+) pole. In this case, the second particle 185c with a large charge amount moves quickly toward the lower electrode 182a, and the first particle 185b with a small charge amount may move slightly near the upper electrode 182b.

Accordingly, the first particle 185b and the second particle 185c are in the state of FIG. 5A described above, so that light may travel only at the front viewing angle, and the share mode may be switched to the privacy mode. In addition, it is possible to secure both the frontal transmittance and the lateral shielding rate.

Next, referring to FIGS. 5A and 6E, even if the voltage applied between the upper electrode 182b and the lower electrode 182a is cut off, the first particle 185b and the second particle 185c due to the nature of the bi-stability ink may maintain their current state (e.g., position and distribution). Therefore, the privacy mode state may be maintained without applying the voltage, the power consumption may be reduced in the privacy mode, and the defects due to the particle agglomeration during the long-term operation may be prevented.

In this way, by applying the bi-stability black first particle 185b and white second particle 185c to the multi-layered structure of the stripe barrier 187 and the active barrier, both the frontal transmittance and lateral shielding rate may be secured. In addition, it is possible to freely switch between the privacy mode and the share mode according to the user needs, reduce the power consumption, and prevent the defects due to the particle agglomeration during the long-term operation. In addition, through the individual driving, some areas may be driven in the share mode and some other areas may be driven in the privacy mode.

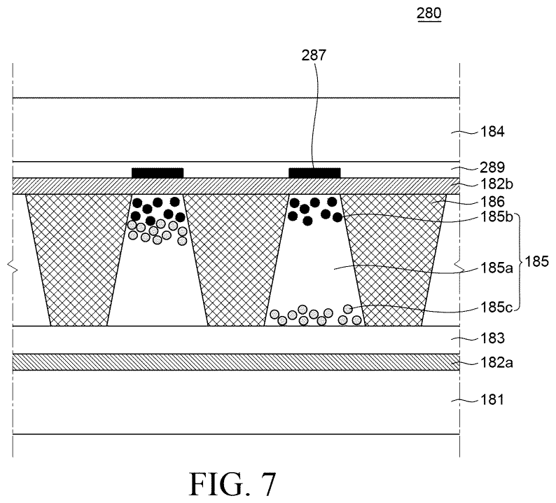

Meanwhile, the barrier of the present disclosure may be disposed on a layer other than the top surface of the upper substrate, and an example in which the barrier is disposed between the upper substrate and the upper electrode will be described in detail below with reference to FIG. 7.

FIG. 7 is a cross-sectional view exemplarily illustrating a viewing angle control film according to a second exemplary embodiment of the present disclosure.

A viewing angle control film 280 of the second exemplary embodiment of the present disclosure in FIG. 7 is different from the first exemplary embodiment of FIGS. 3 and 4 described above only in that a barrier 287 is disposed between the upper substrate 184 and the upper electrode 182b, and other components are substantially the same, and therefore, redundant description thereof will be omitted. The same reference numerals will be used for the same components. Hereinafter, descriptions of the same reference numerals may refer to FIGS. 1 to 6.

Referring to FIG. 7, the viewing angle control film 280 according to the second exemplary embodiment of the present disclosure may largely include an upper electrode 182b, a lower electrode 182a, and a louver pattern, for example, a viewing angle pattern 186 disposed between the upper electrode 182b and the lower electrode 182a.

The lower electrode 182a may be disposed over the lower substrate 181.

The upper electrode 182b may be disposed below the upper substrate 184.

The adhesive layer 183 may be disposed over the lower electrode 182a.

The viewing angle pattern 186 may be disposed on the adhesive layer 183.

The viewing angle control film 280 according to the second exemplary embodiment of the present disclosure may further include the ink layer 185 provided in the space between the plurality of viewing angle patterns 186.

As described above, for example, the ink layer 185 may include the first particle 185b and the second particle 185c provided in the solvent 185a.

In addition, for example, the first particle 185b may be formed of black ink such as carbon, and the second particle 185c may be formed of white ink, but are not limited thereto.

In addition, the first particle 185b and the second particle 185c may have different particle charge amounts. For example, the second particle 185c may have a larger particle charge amount than the first particle 185b.

The first particle 185b and the second particle 185c may be the bi-stability electrophoretic ink.

The upper electrode 182b may be disposed over the viewing angle pattern 186 and the ink layer 185.

In the second exemplary embodiment of the present disclosure, for example, the stripe-type barrier 287 may be disposed on the top surface of the upper electrode 182b.

For example, the barrier 287 may be formed of a black-based material.

For example, the barrier 287 may be positioned corresponding to the space between the plurality of viewing angle patterns 186 on which the ink layer 185 is disposed.

For example, the plurality of barriers 287 may be disposed side by side in one direction along the respective spaces between the plurality of viewing angle patterns 186.

A protective layer 289 may be disposed on the barrier 287 to cover the barrier 287.

For example, the protective layer 289 may be formed of an insulating material, but is not limited thereto.

In addition, the upper substrate 184 may be disposed over the protective layer 289.

The second exemplary embodiment of the present disclosure exemplifies the case where the barrier 287 is disposed on the top surface of the upper electrode 182b, but is not limited thereto, and the barrier may be disposed on another layer between the upper electrode 182b and the upper substrate 184.

In addition, substantially similar to the first exemplary embodiment described above, according to the second exemplary embodiment of the present disclosure, it is possible to freely switch between the privacy mode and the share mode according to the user needs, reduce the power consumption, and prevent the defects due to the particle agglomeration during the long-term operation. In addition, through the individual driving, some areas may be driven in the share mode and some other areas may be driven in the privacy mode.

Meanwhile, the viewing angle control film of the present disclosure may be disposed between the display panel and the backlight unit, but is not limited thereto and may be disposed over the display panel.

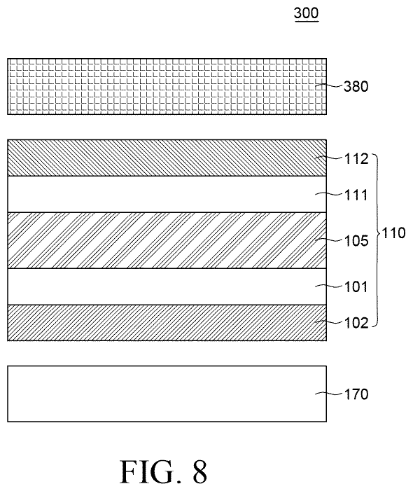

FIG. 8 is a cross-sectional view schematically illustrating a liquid crystal display device of a third exemplary embodiment of the present disclosure.

A liquid crystal display device 300 of the third exemplary embodiment of the present disclosure of FIG. 8 is different from the first exemplary embodiment of the present disclosure in FIGS. 2 to 5 described above in that the viewing angle control film 380 is disposed over the display panel 110, and other components are substantially the same, and therefore, redundant description thereof will be omitted. The same reference numerals will be used for the same components. Hereinafter, descriptions of the same reference numerals may refer to FIGS. 1 to 6.

Referring to FIG. 8, the liquid crystal display device 300 according to the third exemplary embodiment of the present disclosure may include the display panel 110 and the backlight unit 170 that is disposed below the display panel 110 to provide a light source.

The display panel 110 may include the lower substrate 101, the upper substrate 111, and the liquid crystal layer 105 injected between the lower substrate 101 and the upper substrate 111, and a plurality of pixels may be disposed in a matrix form.

The polarizers 102 and 112 may each be attached to outsides of the lower substrate 101 and the upper substrate 111 of the display panel 110 configured as described above, and the alignment film for setting a pre-tilt angle of a liquid crystal may be formed on an inside thereof.

Meanwhile, according to the third exemplary embodiment of the present disclosure, a viewing angle control film 380 is provided over the display panel 110 to control the viewing angle.

The viewing angle control film 380 according to the third exemplary embodiment of the present disclosure is configured by an active barrier and a black stripe barrier, as described above. Detailed descriptions of the viewing angle control film 380 may refer to the above-described first and second exemplary embodiments.

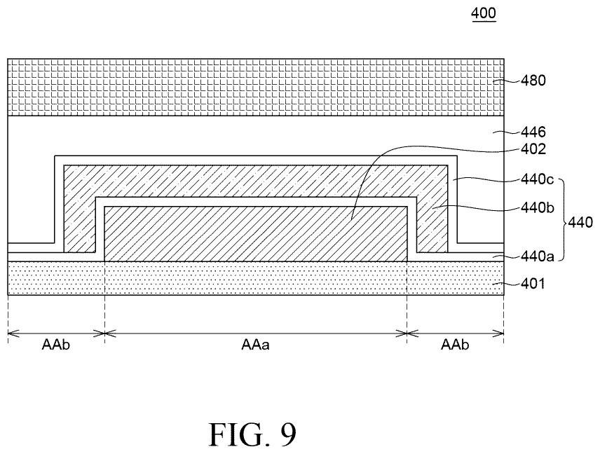

Meanwhile, the present disclosure may include the organic electroluminescent display device other than the liquid crystal display device as the display device, and will be described in detail with reference to FIG. 9.

FIG. 9 is a cross-sectional view schematically illustrating an organic electroluminescent display device according to a fourth exemplary embodiment of the present disclosure.

FIG. 9 illustrates an example of a top emission-type organic electroluminescent display device 400, but the present disclosure is not limited thereto and can also be applied to a back emission type.

Referring to FIG. 9, the organic electroluminescent display device 400 according to the fourth exemplary embodiment includes a panel part 401 divided into an active area and a pad area, and a thin film encapsulation layer 440 that is provided on the panel part 401 while covering the active area.

Here, the active area is a pixel part AAa where a plurality of sub-pixels is disposed to actually display an image, and an outer part AAb that is formed on the outside of the pixel part AAa to transmit signals applied from the outside to the pixel part AAa.

In addition, the thin film encapsulation layer 440 may be disposed on the panel part 401 while covering the pixel part AAa and a portion of the outer part AAb.

A panel element 402 may be disposed on the top surface of the panel part 401 in the pixel part AAa. Here, for convenience of description, the term “panel element 402” is used to collectively refer to an organic light emitting diode and a TFT array for driving the organic light emitting diode.

A thin film encapsulation layer 440 may be disposed on the top surface of the panel part 401 to cover the panel element 402.

To describe in detail the thin film encapsulation layer 440, a primary protective film 440a, an organic film 440b, and a secondary protective film 440c are sequentially formed as an encapsulation means on the substrate provided with the panel element 402, so the thin film encapsulation layer 440 may be formed. However, as described above, the number of inorganic films and organic films constituting the thin film encapsulation layer 440 is not limited thereto.

Meanwhile, the viewing angle control film 480 for controlling the viewing angle may be provided on the thin film encapsulation layer 440 configured as described above. Optionally, as shown in FIG. 9, an additional layer 446 can be provided between the thin film encapsulation layer 440 and the viewing angle control film 480, which can be, for example, a flattening layer.

The viewing angle control film 480 according to the fourth exemplary embodiment of the present disclosure is configured by the active barrier and the black stripe barrier, as described above. Detailed descriptions of the viewing angle control film 480 may refer to the above-described first and second exemplary embodiments.

The exemplary embodiments of the present disclosure can also be described as follows:

According to an aspect of the present disclosure, there is provided a viewing angle control film. The viewing angle control film includes a lower electrode, a plurality of viewing angle patterns disposed over the lower electrode, an ink layer disposed in a space between the plurality of viewing angle patterns, an upper electrode disposed over the plurality of viewing angle patterns and the ink layer and a plurality of barriers disposed over the upper electrode, the ink layer may include a first particle and a second particle having different particle charge amounts.

Each of the plurality of viewing angle patterns may be made of (or may comprise) a transparent material having a trapezoidal shape in which a top surface facing the upper electrode may be wider than a bottom surface facing the lower electrode.

The plurality of viewing angle patterns may be disposed side by side in one direction, and the respective spaces between the plurality of viewing angle patterns may be disposed side by side in the one direction along the plurality of viewing angle patterns.

The upper electrode and the lower electrode may be formed of a transparent conductive material.

Each of the plurality of barriers may be made of (or may comprise) a black-based material.

Each of the plurality of barriers may be positioned corresponding to the space between the plurality of viewing angle patterns where the ink layer may be disposed.

The plurality of barriers may be disposed side by side in the one direction.

The first particle may be made of (or may comprise) black ink, and the second particle may be made of (or may comprise) a white ink.

The second particle may have a larger particle charge amount than the first particle.

The first particle and the second particle may be made of (or may comprise) bi-stability electrophoretic ink.

In case no voltage is applied between the upper electrode and the lower electrode, the first particle and the second particle maintain their positions within the ink layer.

In case a voltage is applied between the upper electrode and the lower electrode, the first particle and the second particle move toward the electrode to which a negative (−) voltage is applied.

In case the voltage applied between the upper electrode and the lower electrode is cut off, the first particle and the second particle maintain their positions within the ink layer.

According to an aspect of the present disclosure, there is provided a display device. The display device includes a display panel and a viewing angle control film positioned over or below the display panel, the viewing angle control film includes a lower electrode, a plurality of viewing angle patterns disposed over the lower electrode, an ink layer disposed in a space between the plurality of viewing angle patterns, an upper electrode disposed over the plurality of viewing angle patterns and the ink layer and a plurality of barriers disposed over the upper electrode, and the ink layer may include a first particle and a second particle having different particle charge amounts.

Each of plurality of viewing angle patterns may be made of (or may comprise) a transparent material having a trapezoidal shape in which a top surface facing the upper electrode may be wider than a bottom surface facing the lower electrode.

The plurality of viewing angle patterns may be disposed side by side in one direction, and the space between the plurality of viewing angle patterns may be disposed side by side in the one direction along the plurality of viewing angle patterns.

The upper electrode and the lower electrode may be made of (or may comprise) a transparent conductive material.

Each of the plurality of barriers may be made of (or may comprise) a black-based material.

Each of the plurality of barriers may be positioned corresponding to the space between the plurality of viewing angle patterns where the ink layer may be disposed.

The plurality of barriers may be disposed side by side in the one direction.

The first particle may be made of (or may comprise) black ink, and the second particle may be made of (or may comprise) a white particle.

The second particle may have a larger particle charge amount than the first particle.

The first particle and the second particle may be made of (or may comprise) bi-stability electrophoretic ink.

In case no voltage may be applied (or in the absence of a voltage applied) between the upper electrode and the lower electrode, the first particle and the second particle may maintain their positions within the ink layer and maintain a share mode or a privacy mode.

In case the voltage may be applied (or in response to applying the voltage) between the upper electrode and the lower electrode, the first particle and the second particle may move toward an electrode to which a negative (−) voltage may be applied and switch from the share mode or the privacy mode to the privacy mode or the share mode, respectively.

In case the voltage applied between the upper electrode and the lower electrode may be cut off (or in response to cutting off the voltage applied between the upper electrode and the lower electrode), the first particle and the second particle may maintain their positions within the ink layer and maintain the privacy mode or the share mode.

The display device may further include a backlight unit, and the viewing angle control film may be provided between the display panel and the backlight unit.

According to an aspect of the present disclosure, there is provided a display device. The display device may include a panel part on which a panel element is disposed, an encapsulation layer covering the panel element, and a viewing angle control film according to the abovementioned aspect of the present disclosure, disposed on the encapsulation layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A viewing angle control film, comprising:
a lower electrode;
a plurality of viewing angle patterns disposed over the lower electrode;
an ink layer disposed in a space between the plurality of viewing angle patterns;
an upper electrode disposed over the plurality of viewing angle patterns and the ink layer; and
a plurality of barriers disposed over the upper electrode,
wherein the ink layer includes a first particle and a second particle having different particle charge amounts.

2. The viewing angle control film of claim 1, wherein each of the plurality of viewing angle patterns comprises a transparent material having a trapezoidal shape in which a top surface facing the upper electrode is wider than a bottom surface facing the lower electrode.

3. The viewing angle control film of claim 1, wherein the plurality of viewing angle patterns is disposed side by side in one direction, and
wherein the respective spaces between the plurality of viewing angle patterns are disposed side by side in the one direction along the plurality of viewing angle patterns.

4. The viewing angle control film of claim 1, wherein the upper electrode and the lower electrode comprise a transparent conductive material.

5. The viewing angle control film of claim 1, wherein each of the plurality of barriers comprises a black-based material.

6. The viewing angle control film of claim 1, wherein each of the plurality of barriers is positioned corresponding to the space between the plurality of viewing angle patterns where the ink layer is disposed.

7. The viewing angle control film of claim 3, wherein the plurality of barriers is disposed side by side in the one direction.

8. The viewing angle control film of claim 1, wherein the first particle comprises black ink, and the second particle comprises a white ink.

9. The viewing angle control film of claim 8, wherein the second particle has a larger particle charge amount than the first particle.

10. The viewing angle control film of claim 1, wherein the first particle and the second particle comprise bi-stability electrophoretic ink.

11. The viewing angle control film of claim 1, wherein in an absence of a voltage applied between the upper electrode and the lower electrode, the first particle and the second particle are to maintain their positions within the ink layer.

12. The viewing angle control film of claim 11, wherein in response to applying a voltage between the upper electrode and the lower electrode, the first particle and the second particle are to move toward the electrode to which a negative voltage is applied.

13. The viewing angle control film of claim 12, wherein in response to cutting off the voltage applied between the upper electrode and the lower electrode, the first particle and the second particle are to maintain their positions within the ink layer.

14. A display device, comprising:
a display panel; and
a viewing angle control film positioned over or below the display panel,
wherein the viewing angle control film includes:
a lower electrode;
a plurality of viewing angle patterns disposed over the lower electrode;
an ink layer disposed in a space between the plurality of viewing angle patterns;
an upper electrode disposed over the plurality of viewing angle patterns and the ink layer; and
a plurality of barriers disposed over the upper electrode, and
wherein the ink layer includes a first particle and a second particle having different particle charge amounts.

15. The display device of claim 14, wherein each of plurality of the viewing angle patterns comprises a transparent material having a trapezoidal shape in which a top surface facing the upper electrode is wider than a bottom surface facing the lower electrode.

16. The display device of claim 14, wherein the plurality of viewing angle patterns is disposed side by side in one direction, and
wherein the space between the plurality of viewing angle patterns is disposed side by side in the one direction along the plurality of viewing angle patterns.

17. The display device of claim 14, wherein the upper electrode and the lower electrode comprise a transparent conductive material.

18. The display device of claim 14, wherein each of the plurality of barriers comprises a black-based material.

19. The display device of claim 14, wherein each of the plurality of barriers is positioned corresponding to the space between the plurality of viewing angle patterns where the ink layer is disposed.

20. The display device of claim 16, wherein the plurality of barriers is disposed side by side in the one direction.

21. The display device of claim 14, wherein the first particle comprises black ink, and the second particle comprises a white ink.

22. The display device of claim 21, wherein the second particle has a larger particle charge amount than the first particle.

23. The display device of claim 22, wherein the first particle and the second particle comprise bi-stability electrophoretic ink.

24. The display device of claim 23, wherein in an absence of a voltage applied between the upper electrode and the lower electrode, the first particle and the second particle are to maintain their positions within the ink layer and maintain a share mode or a privacy mode.

25. The display device of claim 24, wherein in response to applying the voltage between the upper electrode and the lower electrode, the first particle and the second particle are to move toward an electrode to which a negative voltage is applied and switch from the share mode or the privacy mode to the privacy mode or the share mode, respectively.

26. The display device of claim 25, wherein in response to cutting off the voltage applied between the upper electrode and the lower electrode, the first particle and the second particle are to maintain their positions within the ink layer and maintain the privacy mode or the share mode.

27. The display device of claim 14, further comprising a backlight unit positioned below the display panel, wherein the viewing angle control film is provided between the display panel and the backlight unit.
